(19) United States
(12) Patent Application Publication
(10) Pub. No.: US 2026/0372156 A1
(43) Pub. Date: Nov. 19, 2026

(54) SEMICONDUCTOR BONDING APPARATUS

(71) Applicant: Samsung Electronics Co., Ltd., Suwon-si (KR)

(72) Inventors: Taejae Park, Suwon-si (KR); Chaein Moon, Suwon-si (KR); Cheolmin Kim, Daejeon (KR); Inkyu Park, Daejeon (KR); Donho Lee, Daejeon (KR); Sunchul Kim, Suwon-si (KR)

(73) Assignee: Korea Advanced Institute of Science and Technology, Daejeon (KR)

(21) Appl. No.: 19/432,494

(22) Filed: Dec. 24, 2025

(30) Foreign Application Priority Data
May 16, 2025 (KR) 10-2025-0063615

(51) Int. Cl. H10W 72/00; B23K 1/00; B23K 1/002; B23K 3/047; B23K 101/40

(52) U.S. Cl. CPC H10W 72/07235; B23K 1/0016; B23K 1/002; B23K 3/0475; H10W 72/07141; B23K 2101/40

(57) ABSTRACT

A semiconductor bonding apparatus includes a magnetic core including (i) a core portion extending in a direction and (ii) a shielding portion on a top of the core portion; and a magnetic induction coil including a wire around the core portion of the magnetic core. The wire of the magnetic induction coil defines a hollow space that receives the core portion of the magnetic core. The wire of the magnetic induction coil is wound on a horizontal plane that crosses the direction. The shielding portion of the magnetic core extends at least partially over an upper portion of the magnetic induction coil.

### CROSS-REFERENCE TO RELATED APPLICATIONS

This application claims the benefit under 35 USC 119(a) of an earlier filing date and right of priority to Korean Patent Application No. 10-2025-0063615 filed on May 16, 2025 in the Korean Intellectual Property Office, the disclosure of which is incorporated herein by reference in its entirety.

### TECHNICAL FIELD

The present disclosure relates to semiconductor bonding apparatus.

### BACKGROUND

A semiconductor package includes at least one semiconductor chip that is implemented in a form suitable for use in electronic products. Typically, semiconductor packages are manufactured by mounting semiconductor chips on a printed circuit board (hereinafter, “PCB”) and electrically connecting the same using bonding wires or solder bumps.

Solder bumps may not use wire connections between the semiconductor chip and the substrate, which saves space, unlike bonding wires, and greatly improves electrical performance by reducing wiring length. Soldering technology utilizing high-frequency induction heating may be used as one of the bonding processes for semiconductor chips using solder bumps.

### SUMMARY

Soldering equipment utilizing high-frequency induction heating may include a spiral electromagnetic induction coil and a power supply system, and may selectively use a cylindrical ferrite core to improve soldering performance. For example, when a chip component is mounted on a PCB and an alternating current is applied to the electromagnetic induction coil of a high-frequency induction heating device, a magnetic field is generated, an eddy current is generated inside the solder bump due to this magnetic field, and the solder bump is melted by utilizing the electromagnetic induction heating effect, which generates Joule heat due to the internal resistance of the solder bump, thereby performing soldering and packaging.

However, in the case of soldering equipment for high-frequency induction heating, the magnetic field generated by the electromagnetic induction coil may not be effectively concentrated on the solder bump, so the efficiency (resolution) of the electromagnetic induction heating is poor, and as a result, it may be difficult to inductively heat pins with a very small pitch of, e.g., 700 µm or less located on the PCB.

Example implementations provide a semiconductor bonding apparatus that may effectively concentrate a magnetic field generated by a magnetic induction coil on a solder bump.

Example implementations provide a semiconductor bonding apparatus in which efficiency of induction heating during soldering may be improved and the quality of soldering and packaging may also be improved.

According to example implementations, a semiconductor bonding apparatus includes a magnetic induction coil in which a wire is wound on the same horizontal plane such that an outer diameter thereof gradually increases, and which includes a hollow space in a center in which the wire is not wound; and a magnetic core including a core portion inserted into and disposed in the hollow space, and a shielding portion disposed on a top of the core portion and at least partially covering an upper portion of the magnetic induction coil.

According to example implementations, a semiconductor bonding apparatus includes a magnetic induction coil in which a wire is wound in a spiral manner so that an outer diameter thereof gradually increases upwardly in a vertical direction and which includes a hollow space in a center in which the wire is not wound; and a magnetic core including a core portion inserted into and disposed in the hollow space, and a shielding portion disposed on a top of the core portion and at least partially covering an upper portion of the magnetic induction coil.

According to example implementations, a semiconductor bonding apparatus includes a magnetic induction coil in which a wire is wound in a spiral manner along a vertical direction so as to have constant outer diameter and which includes a hollow space in a center in which the wire is not wound; and a magnetic core including a core portion inserted into and disposed in the hollow space and a shielding portion disposed on a top of the core portion and covering an upper portion of the magnetic induction coil.

### BRIEF DESCRIPTION OF DRAWINGS

The above and other aspects, features, and advantages of the present disclosure will be more clearly understood from the following detailed description, taken in conjunction with the accompanying drawings.

FIG. 1A is a perspective view illustrating a semiconductor bonding apparatus according to an example implementation.

FIG. 1B is a perspective view illustrating a magnetic core according to an example implementation.

FIG. 1C is a perspective view illustrating a magnetic induction coil according to an example implementation.

FIG. 2A is a cross-sectional view illustrating the semiconductor bonding apparatus of FIG. 1A as viewed in the I-I’ direction.

FIG. 2B is a cross-sectional view illustrating a semiconductor bonding apparatus according to another implementation as viewed in the I-I’ direction.

FIG. 3 is a cross-sectional view illustrating a semiconductor bonding apparatus according to another implementation as viewed in the I-I’ direction.

FIG. 4 is a cross-sectional view illustrating a semiconductor bonding apparatus according to another implementation as viewed in the I-I’ direction.

FIG. 5 is a cross-sectional view illustrating a semiconductor bonding apparatus according to another implementation as viewed in the I-I’ direction.

FIG. 6 is a cross-sectional view illustrating a semiconductor bonding apparatus according to another implementation when viewed in the I-I’ direction.

FIG. 7 is a cross-sectional view illustrating a semiconductor bonding apparatus according to another implementation when viewed in the I-I’ direction.

FIG. 8 is a cross-sectional view illustrating a semiconductor bonding apparatus according to another implementation when viewed in the I-I’ direction.

FIGS. 9A and 9B are examples illustrating the heating state of a solder bump when soldering using a semiconductor bonding apparatus according to an example implementation of the present disclosure.

FIG. 10A and 10B are examples illustrating the heating state of a solder bump when soldering using a semiconductor bonding apparatus according to a comparative example.

FIG. 11 is a graph illustrating the heating state of a solder bump according to the chip pad size of semiconductor bonding apparatuses according to example implementations of the present disclosure and comparative examples.

### DETAILED DESCRIPTION

Hereinafter, example implementations will be described with reference to the accompanying drawings.

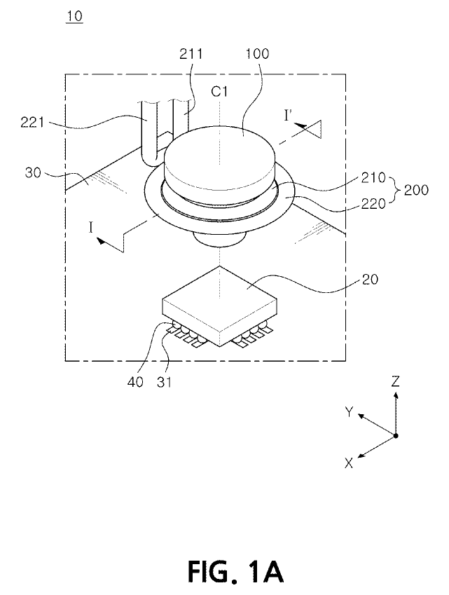

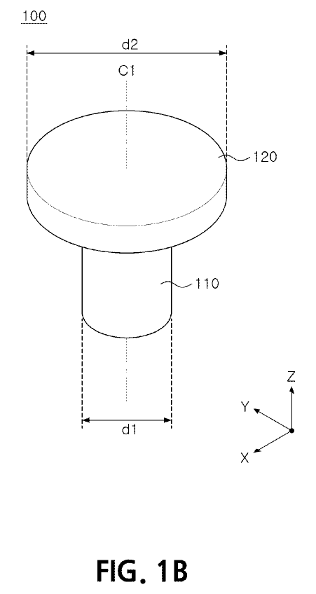

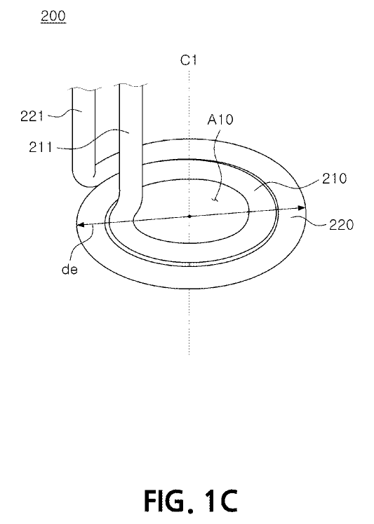

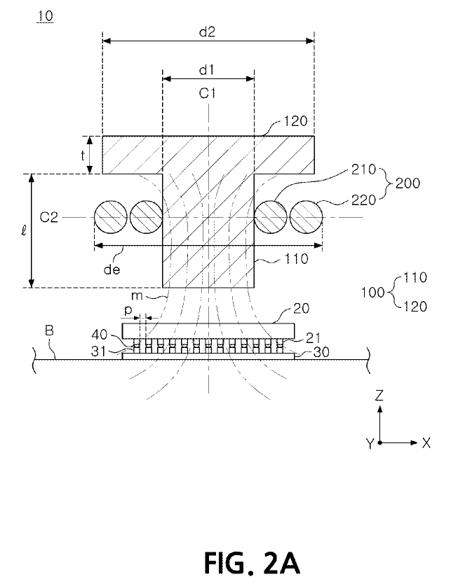

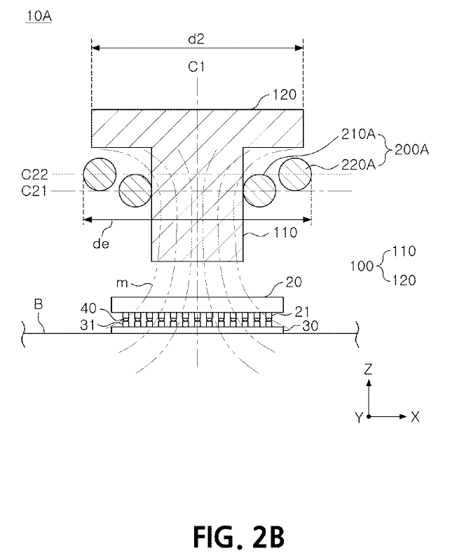

FIG. 1A is a perspective view illustrating a semiconductor bonding apparatus according to an example implementation. FIG. 1B is a perspective view illustrating a magnetic core according to an example implementation. FIG. 1C is a perspective view illustrating a magnetic induction coil according to an example implementation. In addition, FIG. 2A is a cross-sectional view illustrating the semiconductor bonding apparatus of FIG. 1A as viewed in the I-I’ direction.

Referring to FIGS. 1A, 1B and 1C and 2A, a semiconductor bonding apparatus 10 according to an example implementation (Example 1) of the present disclosure may electrically connect a semiconductor chip 20 to a substrate 30 through a solder bump 40. This soldering may be performed while the substrate 30 is supported on a base plate B.

A semiconductor chip 20 may perform a computational function, a control function, a storage function or the like in an electronic device. The semiconductor chip 20 may be, for example, a logic chip or a memory chip. For example, if the semiconductor chip 20 is a logic chip, the semiconductor chip 20 may be a central processing unit (CPU), a controller, an application specific integrated circuit (ASIC), or the like. As another example, if the semiconductor chip 20 is a memory chip, the semiconductor chip 20 may be a volatile memory chip such as a Dynamic Random Access Memory (DRAM), a Static RAM (SRAM), or the like, or a nonvolatile memory chip such as a Phase-change RAM (PRAM), a Magnetoresistive RAM (MRAM), a Ferroelectric RAM (FeRAM), a Resistive RAM (RRAM), or the like.

The semiconductor chip 20 may include a chip pad 21. The chip pad 21 is a conductive pad and may be formed of a low resistivity metal such as aluminum, copper, or the like, but is not limited thereto. In the case of the chip pad 21, at least one chip pad may be provided on at least one surface of the semiconductor chip 20. The chip pad 21 may be electrically connected to the integrated circuit of the semiconductor chip 20 and may input and output electrical signals of the semiconductor chip 20.

The substrate 30 may be, for example, a printed circuit substrate (PCB). The substrate 30 may include a substrate pad 31. The substrate pad 31 is a conductive pad and may be formed of a low resistivity metal such as aluminum or copper, but is not limited thereto. At least one substrate pad 31 may be provided on one surface of the substrate 30. The substrate pad 31 may input and output electrical signals of the semiconductor chip 20 to an external device.

The solder bump 40 may serve as a bonding agent for bonding the semiconductor chip 20 to the substrate 30. In addition, the solder bump 40 is a conductive protrusion for electrically connecting the semiconductor chip 20 and the substrate 30, and may serve to increase the height of the electrode to facilitate flip chip. This solder bump 40 may be interposed between the chip pad 21 provided on the lower surface of the semiconductor chip 20 and the substrate pad 31 provided on the upper surface of the substrate 30.

The solder bump 40 may be formed of an electrically conductive material. The solder bump 40 may have various shapes. For example, the solder bump 40 may have a ball shape. However, the present disclosure is not limited thereto, and the solder bump 40 may be provided in various shapes such as a cylinder, a polygonal column, or a polyhedron.

In the case as above, the semiconductor bonding apparatus 10 may bond the semiconductor chip 20 to the substrate 30 by melting the solder bump 40 using non-contact induction heating to flow between the chip pad 21 and the substrate pad 31 for soldering. The bonded chip pad 21 and substrate pad 31 may be electrically connected to various types of individual elements formed on the semiconductor chip 20 and the substrate 30 via the solder bump 40.

The semiconductor bonding apparatus 10 may include a magnetic core 100 and a magnetic induction coil 200.

The magnetic core 100 may concentrate magnetic induction generated by the magnetic induction coil 200. The magnetic core 100 may include a core portion 110 and a shielding portion 120.

The core portion 110 may be inserted and disposed within a hollow space A10 of the magnetic induction coil 200 to be described later to concentrate magnetic induction. The core portion 110 may be provided in various shapes such as a cylinder, a quadrangular column, or a polygonal column. Hereinafter, the description will be made focusing on an example implementation in which the core portion 110 has a cylinder shape. In this case, the core portion 110 may have a circular cross-section with a predetermined diameter (hereinafter, a first diameter) d1 based on a direction (hereinafter, a horizontal direction) (X-Y) parallel to a horizontal plane (for example, an X-Y plane).

The shielding portion 120 may at least partially cover the upper portion of the magnetic induction coil 200. In more detail, the shielding portion 120 may be disposed on the top of the core portion 110 to cover the core portion 110 located therebelow.

The shielding portion 120 may be provided in various shapes, such as a circular plate or a quadrangular plate. For example, the shielding portion 120 may have a disk shape with a circular cross-section with a predetermined diameter (hereinafter, a second diameter) d2. In this case, the shielding portion 120 may be disposed coaxially with the core portion 110. For example, the centers of the shielding portion 120 and the core portion 110 may be disposed on the same line along the virtual center line (hereinafter, the first center line) C1 and the vertical direction (Z).

The shielding portion 120 may have a larger diameter than a diameter of the core portion 110. For example, the second diameter d2 may be larger than the first diameter d1. Accordingly, the shielding portion 120 may protrude radially outward from the upper end of the core portion 110. In this case, the radial direction may refer to the radial direction of the core portion 110 having a cylindrical shape. In this way, the shielding portion 120 having the second diameter d2 is disposed on the top of the core portion 110 having the first diameter d1, so that the upper portion of the core portion 110 may be shielded by the shielding portion 120.

The shielding portion 120 may have a thickness t different from the length l of the core portion 110. In more detail, the thickness t of the shielding portion 120 may be thinner than the length l of the core portion 110. However, the present disclosure is not limited thereto, and the thickness t of the shielding portion 120 may be the same as the length l of the core portion 110.

Meanwhile, the magnetic core 100 may be a dust core. In this case, the magnetic core 100 may be formed integrally of the core portion 110 and the shielding portion 120. The dust core may be manufactured by combining fine iron (Fe) powder with a binder. Accordingly, the magnetic core 100 according to an example implementation has higher structural flexibility than a general ferrite core, so that it is easy to manufacture a shape having a shielding portion 120 of various shapes and/or sizes, and as a result, an optimal design of the magnetic core 100 may be possible. For example, the shape or size of the magnetic core 100 may be appropriately and easily changed and manufactured based on the specifications of the semiconductor bonding apparatus 10 and/or the type of the semiconductor chip 20 to be soldered.

In addition, since the dust core has high magnetic saturation density and excellent magnetic properties compared to the ferrite core, and is also relatively inexpensive, the magnetic core 100 according to an example implementation may be more advantageous in terms of cost efficiency while having the same as or better magnetic properties than the ferrite core.

The magnetic induction coil 200 may be electrically connected to a high-frequency power supply device (not illustrated) to induce electromagnetic energy. To this end, the magnetic induction coil 200 may be an electric wire or wire formed of a metal with high electrical conductivity. The magnetic induction coil 200 may be, for example, a copper wire.

The magnetic induction coil 200 may be in the form of a wire wound. In more detail, the wire may be wound in multiple layers in one direction with the first center line C1 as the center. In addition, the wire may be wound so that an outer diameter of the magnetic induction coil gradually increases on the same horizontal plane (X-Y). Accordingly, the magnetic induction coil 200 may be formed by winding one wire so that a winding radius thereof gradually increases on the same plane (X-Y) while having the same center C1. At this time, the wire may be wound in a circular or oval shape, for example. Accordingly, the magnetic induction coil 200 may include a coil portion (hereinafter, referred to as a first coil portion) 210 disposed relatively radially inwardly and a coil portion (hereinafter, referred to as a second coil portion) 220 disposed relatively radially outwardly. Hereinafter, for convenience of explanation, the magnetic induction coil 200 is described based on an example implementation including two coil portions, for example, a first coil portion 210 and a second coil portion 220, but is not limited thereto.

A hollow space A10 may be formed inside the first coil portion 210. The hollow space A10 is a part where no wire is wound, and a core portion 110 may be inserted into and disposed in the hollow space A10. At this time, the hollow space A10 may have a diameter that is the same as or similar to the first diameter d1 of the core portion 110. The core portion 110 may be connected to the magnetic induction coil 200 while being inserted through the hollow space A10. For example, the core portion 110 may be coupled to the magnetic induction coil 200 in a manner in which the wire is wound to be firmly adhered to the outer surface of the core portion 110, but is not limited thereto.

The two ends 211 and 221 of the magnetic induction coil 200 may be electrically connected to a high-frequency power supply unit (not illustrated). In more detail, the end 211 of the first core portion 110 and the end 221 of the second core portion 110 may be electrically connected to the high-frequency power supply unit. When current is supplied from the high-frequency power supply unit to the magnetic induction coil 200, a magnetic field m may be formed around the magnetic induction coil 200. An eddy current may be generated inside the solder bump 40 by this magnetic field m. Eddy current is lost through the Joule heating and heat is generated, and by such high-frequency induction heating, the solder bump 40 may be heated and melted. At this time, since the magnetic induction coil 200 has a wound shape in which the outer diameter gradually increases on the same horizontal plane (X-Y), the strength of the formed magnetic field m may increase, and thereby the soldering quality may be improved.

The magnetic induction coil 200 may be disposed coaxially with the magnetic core 100. In more detail, the centers of the magnetic induction coil 200, the core portion 110, and the shielding portion 120 may be disposed on the same line as the first center line C1 described above.

The second diameter d2 of the shielding portion 120 may be the same as or similar to the maximum outer diameter de of the magnetic induction coil 200. For example, the second diameter d2 may be smaller than the maximum outer diameter de mentioned above, and as another example, the second diameter d2 may be equal to the maximum outer diameter de mentioned above. Accordingly, the shielding portion 120 may at least partially cover the upper portion of the magnetic induction coil 200. For example, the upper portion of the magnetic induction coil 200 may be at least partially shielded by the shielding portion 120.

Generally, when soldering using a semiconductor bonding apparatus, a high frequency of several hundred kHz (for example, 560 kHz) is applied to the magnetic induction coil to generate a magnetic field, and the magnetic core concentrates the magnetic field on the solder bump to heat the solder bump. However, the existing magnetic core is formed of a simple cylindrical ferrite core and cannot effectively concentrate the magnetic field on the solder bump. Therefore, the efficiency of high-frequency induction heating (electromagnetic induction heating) is reduced, and there is a problem that it is difficult to perform soldering when the pitch p is fine, for example, 700 µm or less. In this case, the pitch p may refer to the linear distance between two adjacent solder bumps 40 among the plurality of solder bumps 40 interposed on the substrate 30.

In comparison, in the case of the semiconductor bonding apparatus 10 according to an example implementation, the upper part of the magnetic induction coil 200 is shielded by the shielding portion 120 on the top of the core portion 110, so that the magnetic field m generated by the magnetic induction coil 200 may be effectively concentrated on the solder bumps 40 located below the magnetic induction coil 200 and the core portion 110.

In addition, the efficiency of the above-mentioned high frequency induction heating may be improved due to the concentrated magnetic field m. Therefore, even if the solder bumps 40 have a very fine pitch p of about 300 µm, the magnetic field may be concentrated on each solder bump 40 using high-frequency induction heating that uses a frequency of several hundred kHz, and the solder bumps 40 may be efficiently heated. Accordingly, even the solder bumps 40 having a fine pitch p as described above may be melted by induction heating to the melting point (for example, about 217° C.) or higher. As a result, the soldering quality of the semiconductor chip 20 may be further improved.

In addition, the semiconductor bonding apparatus 10 may further include a cooler(not illustrated). The cooler may cool the magnetic core 100 and the magnetic induction coil 200. In an example implementation, the cooler may be configured as a blower. In this case, the cooling unit, which is a blower, may blow cooling gas toward the magnetic core 100 and the magnetic induction coil 200. For example, the cooler may be disposed on the upper or side of the core portion 110 to blow cooling gas toward the magnetic core 100 and the magnetic induction coil 200 along the up-down direction (Z). In this way, the magnetic core 100 and the magnetic induction coil 200 that were heated during soldering may be cooled by the cooling gas supplied from the cooling unit.

However, the present disclosure is not limited to the above-described implementation, and as another example, the cooler may be provided in a form that includes a cooling path through which cooling water flows, thereby cooling the magnetic core 100 and the magnetic induction coil 200.

Meanwhile, although not illustrated in the drawing, the magnetic core 100 on which the magnetic induction coil 200 as described above is wound may be configured to be moved in the X-axis/Y-axis/Z-axis directions by means of a transfer robot (not illustrated). As a result, the semiconductor bonding apparatus 10 may continuously perform soldering on a plurality of semiconductor chips 20. In addition, therefore, not only a two-dimensional substrate 30 but also a three-dimensional substrate (not illustrated) may be easily performed to solder the semiconductor chip 20.

The soldering or cooling of the semiconductor bonding apparatus 10 as described above and/or the movement of the magnetic core 100 by the transfer robot may be controlled by a control unit (not illustrated). At this time, the control unit may be implemented in the form of, for example, a circuit substrate mounted on a control computer of the semiconductor bonding apparatus 10, a computer chip mounted on the circuit substrate, software embedded in a computer chip or embedded in a control computer, or the like, but is not limited thereto.

FIG. 2B is a cross-sectional view showing a semiconductor bonding apparatus according to another implementation as viewed in the I-I’ direction.

Referring to FIG. 2B, a semiconductor bonding apparatus 10A according to another implementation (Example 2) of the present disclosure may include a magnetic core 100 and a magnetic induction coil 200A. At this time, most of the characteristics of the magnetic core 100 and the magnetic induction coil 200A are the same or similar to those of the aforementioned Example 1, and thus overlapping descriptions will be omitted and differences will be described.

In the case of Example 2, the magnetic induction coil 200A may be in the form of one wire wound in multiple layers in one direction centered on the first center line C1. At this time, the wire may be wound so that a winding radius of the wire gradually increases. In addition, the wire may be wound in a spiral shape so that the winding radius of the wire gradually increases in the vertical direction (Z). That is, the outer diameter of the magnetic induction coil may gradually increase along the vertical direction (Z) and along the horizontal direction (X-Y). Accordingly, the magnetic induction coil 200A may wrap around the outer surface of the core portion 110 at least partially.

As illustrated in FIG. 2B, the wire may be wound so that the outer diameter thereof increases toward the upper side (+Z). In this case, the first coil portion 210A may be disposed along the same line along the 2-1 center line C21. In addition, the second coil portion 220A may be disposed along the same line along the 2-2 center line C22 located above the 2-1 center line C21. Accordingly, the second coil portion 220A may be located to be at least partially higher than the first coil portion 210A.

The present disclosure is not limited to the above-described implementation, and as another example, although not illustrated in the drawing, the outer diameter may be increased toward the lower side (-Z), or as another example, the wire may be wound so that the outer diameter is maximum at the center. However, for convenience of explanation, the following description will focus on a case where the magnetic induction coil 200A includes a first coil portion 210A and a second coil portion 220A wound on the upper portion of the first coil portion 210A, and the second coil portion 220A has a larger outer diameter.

In the above case, the second diameter d2 of the shielding portion 120 is provided to be smaller than or equal to the maximum outer diameter de of the magnetic induction coil 200A, to shield the upper portions of the core portion 110 and the magnetic induction coil 200. Accordingly, as in the aforementioned Example 1, the magnetic induction heating efficiency and soldering quality may be improved by effectively concentrating the magnetic flux to the solder bump 40.

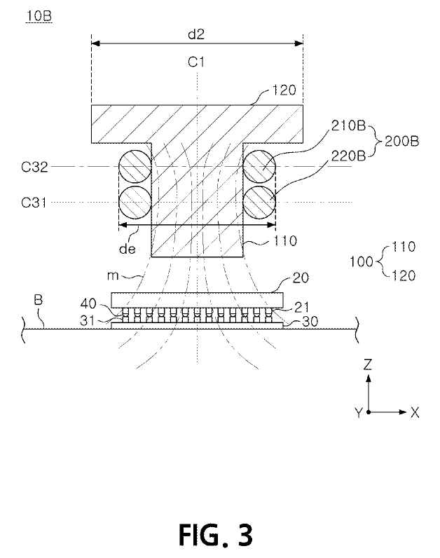

FIG. 3 is a cross-sectional view illustrating a semiconductor bonding apparatus according to another implementation as viewed in the I-I’ direction.

Referring to FIG. 3, a semiconductor bonding apparatus 10B according to another implementation (Example 3) of the present disclosure may include a magnetic core 100 and a magnetic induction coil 200B. At this time, since most of the characteristics of the magnetic core 100 and the magnetic induction coil 200B are the same or similar to those of the aforementioned Example 1, overlapping descriptions will be omitted and descriptions will be focused on differences.

In the case of Example 3, the magnetic induction coil 200B may be in the form of one wire wound in multiple layers along one direction centered on the first center line C1. For example, the wire may be wound with a constant outer diameter along the vertical direction (Z).

In more detail, the magnetic induction coil 200B may be wound to have the same outer diameter de overall along the vertical direction (Z) or the height direction of the core portion 110. For example, the first coil portion 210B may be disposed on the same line along the 2-3 center line C32. In addition, the second coil portion 220B may be disposed on the same line along the 2-4 center line C33. At this time, the first coil portion 210B and the second coil portion 220B may be wound to have the same outer diameter de. By these coil portions 210B and 220B, the outer surface of the core portion 110 may be at least partially wrapped.

As illustrated in FIG. 3, the shielding portion 120 may have a second diameter d2 larger than the maximum outer diameter de of the magnetic induction coil 200B. By shielding the upper portions of the core portion 110 and the magnetic induction coil 200 with the shielding portion 120, and effectively concentrating the magnetic flux on the solder bump 40, magnetic induction heating efficiency and soldering quality may be improved, which is the same as in the above-described implementations.

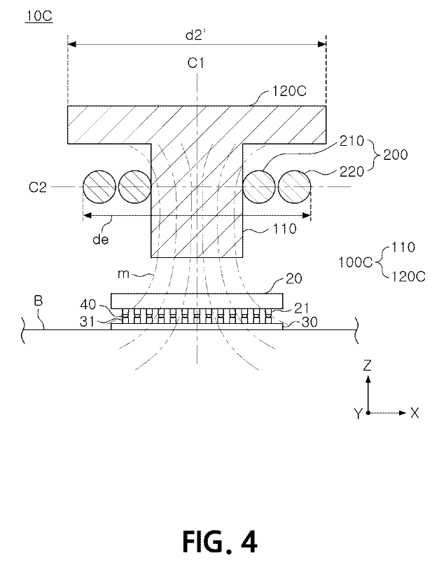

FIG. 4 is a cross-sectional view illustrating a semiconductor bonding apparatus according to another implementation as viewed in the I-I’ direction.

Referring to FIG. 4, a semiconductor bonding apparatus 10C according to another implementation (Example 4) of the present disclosure may include a magnetic core 100C and a magnetic induction coil 200. At this time, since most of the features of the magnetic core 100C and the magnetic induction coil 200 are the same or similar to those of the aforementioned Example 1, overlapping descriptions will be omitted and differences will mainly be explained.

In the case of Example 4, the magnetic core 100C may include a core portion 110 and a shielding portion 120C. At this time, the core portion 110 may have a cylindrical shape having a first diameter d1, similar to the aforementioned implementations. The core portion 110 may be wrapped by the magnetic induction coil 200 wound on the same horizontal plane (X-Y).

The shielding portion 120C may have a second diameter d2’ larger than the maximum outer diameter de of the aforementioned magnetic induction coil 200. Accordingly, the shielding portion 120C may cover the entire upper portion of the magnetic induction coil 200. For example, when viewed from above, the magnetic induction coil 200 may be completely covered by the shielding portion 120C and may not be visible to the naked eye.

As described above, since the second diameter d2’ of the shielding portion 120C is provided to be larger than the maximum outer diameter de of the magnetic induction coil 200, the effect of concentrating the magnetic flux to the solder bump 40 may be further improved by shielding the upper portions of the core portion 110 and the magnetic induction coil 200 as described above.

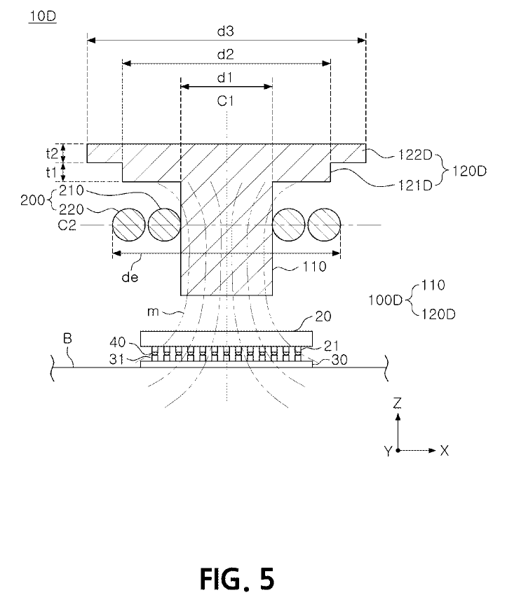

FIG. 5 is a cross-sectional view illustrating a semiconductor bonding apparatus according to another implementation as viewed in the I-I’ direction.

Referring to FIG. 5, a semiconductor bonding apparatus 10D according to another implementation (Example 5) of the present disclosure may include a magnetic core 100D and a magnetic induction coil 200. At this time, since most of the features of the magnetic core 100D and the magnetic induction coil 200 are the same or similar to those of the aforementioned Example 1, overlapping descriptions will be omitted and differences will be mainly explained.

In the case of Example 5, the magnetic core 100D may include a core portion 110 and a shielding portion 120D. At this time, the core portion 110 may have a cylindrical shape having a first diameter d1, similar to the aforementioned implementations.

The shielding portion 120D may be disposed on the core portion 110 to cover the upper portion of the core portion 110 and the magnetic induction coil 200 wound thereon. At this time, the shielding portion 120D may be provided in a multilayer structure. For example, the shielding portion 120D may have a double structure. In this case, the shielding portion 120D may include a first shielding layer 121D and a second shielding layer 122D.

The first shielding layer 121D may be disposed on the core portion 110. At this time, the first shielding layer 121D may have a larger area than the core portion 110. For example, the first shielding layer 121D may have a circular cross-section having a second diameter d2 larger than the first diameter d1 based on the horizontal plane (X-Y) direction. For example, the first shielding layer 121D may have a disk shape having the second diameter d2.

The second shielding layer 122D may be disposed on the first shielding layer 121D. At this time, the second shielding layer 122D may have a larger area than the first shielding layer 121D. For example, the second shielding layer 122D may have a circular cross-section having a third diameter d3 that is larger than the second diameter d2 when based on a direction parallel to the horizontal plane (X-Y) described above. For example, the second shielding layer 122D may have a disk shape having the third diameter d3.

In the above case, the third diameter d3 may be larger than the first diameter d1 and the second diameter d2. As described above, since the first diameter d1 is larger than the first diameter d1 of the core portion 110, the second diameter d2 and the third diameter d3 may also be larger than the first diameter d1. In addition, since the second diameter d2 has a size equal to or similar to the maximum outer diameter de of the magnetic induction coil 200, the third diameter d3 may have a size greater than the maximum outer diameter de. Accordingly, the upper portion of the magnetic induction coil 200 wound on the outer surface of the core portion 110 may be at least partially covered by the first shielding layer 121D. At the same time, the upper portion of the magnetic induction coil 200 may be completely covered by the second shielding layer 122D.

The first shielding layer 121D and the second shielding layer 122D may have the same or similar thicknesses. For example, the thickness (hereinafter, the first thickness) t1 of the first shielding layer 121D and the thickness (hereinafter, the second thickness) t2 of the second shielding layer 122D may be equal. However, the present disclosure is not limited thereto, and as another example, the second thickness t2 may be thinner than the first thickness t1, or the second thickness t2 may be thicker than the first thickness t1.

The core portion 110, the first shielding layer 121D, and the second shielding layer 122D as described above may be stacked along the vertical direction (Z). In more detail, the first shielding layer 121D may be connected to the top of the core portion 110, and the second shielding layer 122D may be connected to the top of the first shielding layer 121D. For example, the magnetic core 100 may be a single structure in which the core portion 110, the first shielding layer 121D, and the second shielding layer 122D are integrally formed. The magnetic core 100 of this type may be a multilayer structure in which the diameter gradually increases (for example, increases from ‘d1 → d2 → d3’) toward the upper side (+Z), as described above.

As described above, since the second diameter d2’ of the shielding portion 120D is provided to be larger than the maximum outer diameter de of the magnetic induction coil 200, the effect of shielding the upper part of the core portion 110 and the magnetic induction coil 200 as described above, thereby concentrating the magnetic flux to the solder bump 40 may be further improved.

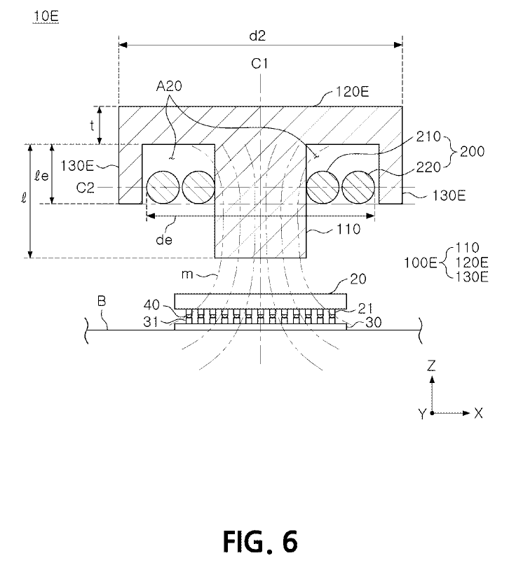

FIG. 6 is a cross-sectional view illustrating a semiconductor bonding apparatus according to another implementation as viewed in the I-I’ direction.

Referring to FIG. 6, a semiconductor bonding apparatus 10E according to another implementation (Example 6) of the present disclosure may include a magnetic core 100E and a magnetic induction coil 200. At this time, since most of the features of the magnetic core 100E and the magnetic induction coil 200 are the same or similar to those of the aforementioned Example 1, overlapping descriptions will be omitted and descriptions will be focused on differences.

In the case of Example 6, the magnetic core 100E may include a core portion 110 and a shielding portion 120E. In addition, the magnetic core 100E may further include a shielding film 130E.

The core portion 110 may be in the shape of a cylinder having a first diameter d1, similar to the aforementioned implementations. The shielding portion 120E may be in the shape of a disk having a second diameter d2 connected to the core portion 110. At this time, the shielding portion 120E may have a second diameter d2 larger than the first diameter d1. In addition, since the second diameter d2 is provided to be larger than the maximum outer diameter de of the magnetic induction coil 200, the upper portion of the core portion 110 and the magnetic induction coil 200 wound thereon may be completely covered by the shielding portion 120E.

The shielding film 130E may be disposed on the shielding portion 120E. In more detail, the shielding film 130E may be disposed on the edge portion of the shielding portion 120E. In this case, the shielding film 130E may be in a form that protrudes toward the lower side (-Z) from the lower surface of the edge portion of the shielding portion 120E. By the shielding film 130E as described above, the outer side of the magnetic induction coil 200 wound around the core portion 110 may be at least partially shielded.

The shielding film 130E may be provided in various forms. For example, the shielding film 130E may have a ring-like shape that extends along the circumferential direction of the core portion 110 and has both ends meeting. In detail, the shielding film 130E may be a single structure in the shape of a ring. In this case, the outer side of the magnetic induction coil 200 may be completely shielded by being surrounded by the shielding film 130E.

As another example, the shielding film 130E may be provided in plural. In this case, the shielding film 130E may have a cross-sectional shape like an arc and may be in the form of a side wall that extends in the vertical direction (Z). This shielding film 130E may be provided in plurality spaced apart from each other at a predetermined interval in the circumferential direction of the shielding portion 120E. In this case, the outer side of the magnetic induction coil 200 may be surrounded by the shielding films 130E and at least partially shielded.

The shielding film 130E according to the Example 6 described above may have a length le shorter than the length l of the core portion 110. In more detail, the shielding film 130E may extend from the lower surface of the shielding portion 120E to the lower surface of the magnetic induction coil 200. Accordingly, the lower surface of the shielding film 130E may be placed on the same horizontal plane (X-Y) as the lower surface of the wire constituting the magnetic induction coil 200.

In the above case, the magnetic induction coil 200 may be disposed within the space (first space) A20 partitioned by the core portion 110, the shielding portion 120E, and the shielding film 130E. In this way, since the magnetic induction coil 200 is accommodated in the first space A20, the upper and outer parts of the core portion 110 and the magnetic induction coil 200 as described above may be shielded. As a result, the magnetic flux may be more effectively concentrated on the solder bump 40, and as a result, the induction heating efficiency and soldering quality may be further improved.

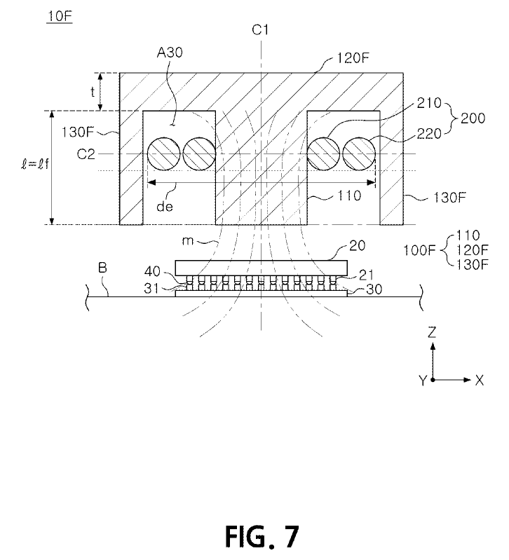

FIG. 7 is a cross-sectional view illustrating a semiconductor bonding apparatus according to another implementation as viewed in the I-I’ direction.

Referring to FIG. 7, a semiconductor bonding apparatus 10F according to another implementation (Example 7) of the present disclosure may include a magnetic core 100F and a magnetic induction coil 200. At this time, since most of the features of the magnetic core 100F and the magnetic induction coil 200 are the same as or similar to the aforementioned Example 1, overlapping descriptions will be omitted and the differences will be mainly described.

The magnetic core 100F of Implementation 7 may include, similarly to Implementation 6, a core portion 110, a shielding portion 120F, and a shielding film 130F.

The core portion 110 may have a cylindrical shape having a first diameter d1. The shielding portion 120E may have a disk shape having a second diameter d2 connected to the core portion 110, and may completely cover the upper portion of the magnetic induction coil 200 by having a second diameter d2 larger than the first diameter d1 and the maximum outer diameter de, as described above.

In addition, the shielding film 130E may be disposed on the edge portion of the shielding portion 120E. In this case, the shielding film 130F may at least partially shield the outside of the magnetic induction coil 200 by protruding toward the lower side (-Z) from the lower surface of the edge portion of the shielding portion 120F.

The shielding film 130F may be provided in various forms. For example, the shielding film 130F may have a ring-like shape extending along the circumference of the core portion 110, so that the outside of the magnetic induction coil 200 may be completely shielded. As another example, a plurality of shielding films 130F in the form of side walls having a cross-sectional shape such as an arc may be provided. Such shielding films 130F may be disposed at predetermined intervals along the circumference of the shielding portion 120F, so that the outside of the magnetic induction coil 200 may be at least partially shielded.

The shielding film 130F according to the above-described Example 7 may have a length lf that is the same as the length l of the core portion 110. In more detail, the shielding film 130F may extend from the lower surface of the shielding portion 120F to the lower surface of the core portion 110. Accordingly, the lower surface of the shielding film 130F may be placed on the same horizontal plane (X-Y) as the lower surface of the core portion 110.

In the above case, the magnetic induction coil 200 may be disposed within the space (second space) A30 partitioned by the core portion 110, the shielding portion 120F, and the shielding film 130F. In this way, since the magnetic induction coil 200 is accommodated in the second space AF0, the upper and outer parts of the core portion 110 and the magnetic induction coil 200 as described above may be shielded. As a result, the magnetic flux may be more effectively concentrated on the solder bump 40, and as a result, the induction heating efficiency and soldering quality may be further improved.

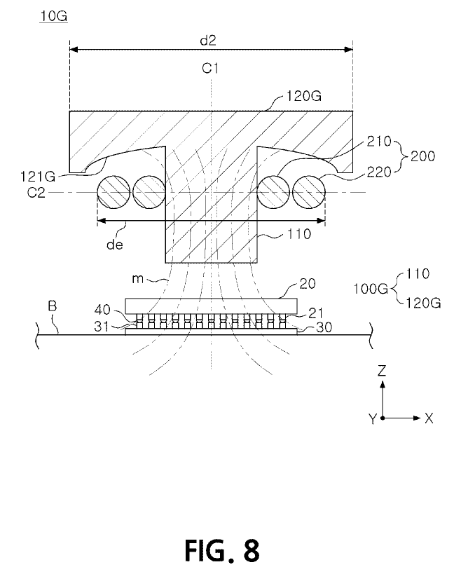

FIG. 8 is a cross-sectional view illustrating a semiconductor bonding apparatus according to another implementation as viewed in the I-I’ direction.

Referring to FIG. 8, a semiconductor bonding apparatus 10G according to another implementation (Example 8) of the present disclosure may include a magnetic core 100G and a magnetic induction coil 200. At this time, since most of the features of the magnetic core 100G and the magnetic induction coil 200 are the same or similar to those of the aforementioned Example 1, overlapping descriptions will be omitted and the differences will be described.

The core portion 110 may be a cylindrical shape having a first diameter d1, and the shielding portion 120E may be a disk shape having a second diameter d2 connected to the core portion 110. At this time, as described above, the second diameter d2 may have a size larger than the first diameter d1 and the maximum outer diameter de, and thus, the upper portion of the magnetic induction coil 200 may be completely covered.

In the case of the magnetic core 100G according to Example 8, the shielding portion 120G may have a concave portion 121G. The concave portion 121G may have a concave shape in the upper side (+Z) on the lower surface of the shielding portion 120G. In this case, the lower surface of the shielding portion 120G may be one surface of the shielding portion 120G facing the magnetic induction coil 200.

By the concave portion 121G, the lower end portion of the shielding portion 120G may be concavely curved inwardly of the shielding portion 120G. At this time, the upper surface of the shielding portion 120G may be provided in a flat shape. Accordingly, the shielding portion 120G has a second diameter d2, and the upper end portion may be a disk shape that is flat while the lower end portion is concave inwardly.

In this way, by shielding the upper portion of the core portion 110 and the magnetic induction coil 200 by the shielding portion 120G in the form of eaves, the effect of concentrating the magnetic flux on the solder bump 40 may be improved as described above. In addition, due to the magnetic flux concentration, the induction heating efficiency of the solder bump 40 by the magnetic field m is improved, and thus the soldering quality is improved, as in the above-described implementations.

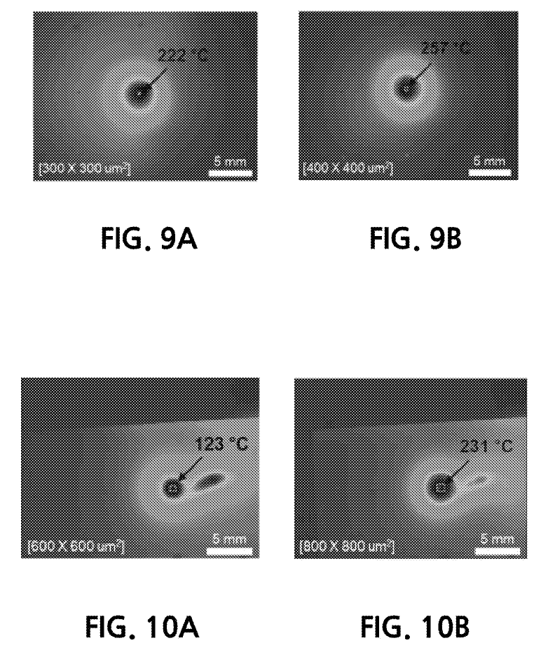

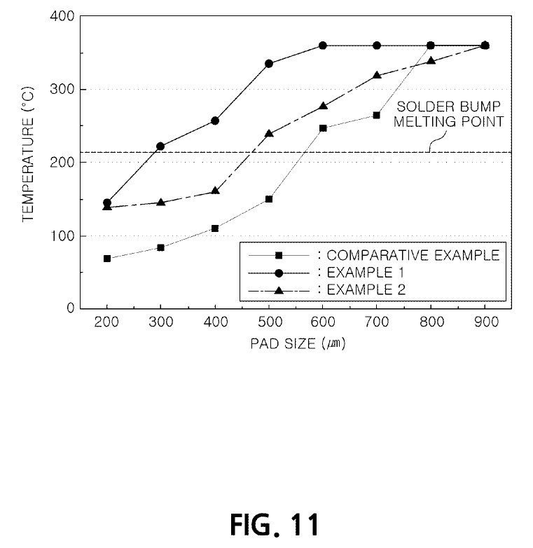

FIGS. 9A and 9B are examples illustrating the heating state of a solder bump during soldering using a semiconductor bonding apparatus according to an example implementation. FIGS. 10A and 10B are examples illustrating the heating state of a solder bump during soldering using a semiconductor bonding apparatus according to a comparative example. FIG. 11 is a graph illustrating the heating state of a solder bump according to the chip pad size of semiconductor bonding apparatuses according to example implementations and comparative examples.

Referring to FIGS. 9A and 9B, when soldering is performed by induction heating the solder bump 40 using the semiconductor bonding apparatus 10, 10A, 10B, 10C, 10D, 10E, 10F, or 10G according to example implementations, even when the pitch p size is 700 µm or less as described above, the magnetic field is concentrated on each solder bump 40, which is thus sufficiently heated to the melting point (for example, about 217˚° C.) or higher. At this time, FIGS. 9A and 9B may be results captured using an infrared camera.

For example, as illustrated in FIG. 9B, when the pitch p is 400 µm (or when the area of the substrate pad 31 is 400*400 µm²), the magnetic flux is concentrated on the solder bump 40 and the solder bump 40 is sufficiently heated to 257° C., which is the melting point or higher. As another example, as illustrated in FIG. 9A, even when the pitch p is 300 µm (or when the area of the substrate pad 31 is 300*300 µm²), the magnetic flux is concentrated on the solder bump 40 and the solder bump 40 is heated to 222° C., which is the melting point or higher.

In comparison, referring to FIGS. 10A and 10B, when soldering is performed by induction heating the solder bump 40 using a semiconductor bonding apparatus (not illustrated) according to a comparative example, each solder bump 40 is not heated to the melting point (for example, about 217° C.) or higher when the pitch p size is 700 µm or less as described above. At this time, FIG. 10A and 10B may be results captured using an infrared camera.

In more detail, as illustrated in FIG. 10B as an example, when the pitch p is 800 µm (or when the area of the substrate pad 31 is 800*800 µm²), the magnetic flux is concentrated on the solder bump 40 and the solder bump 40 is heated to 231° C., which is the melting point or higher. However, as illustrated in FIG. 10A, when the pitch p is 600 µm (or when the area of the substrate pad 31 is 300*300 µm²), the solder bump 40 is not heated to a melting point or a higher temperature because the magnetic flux is not sufficiently concentrated on the solder bump 40.

In addition, referring to FIG. 11, the semiconductor bonding apparatus 10 or 10A according to Implementations 1 and 2 of the present disclosure may heat solder bumps 40 having a smaller pitch p than the comparative example to the melting point or higher. In particular, in the case of an example implementation in which the magnetic core 100 includes a shielding portion 120 and the magnetic induction coil 200 is wound around the core portion 110 so that the outer diameter gradually increases on the same horizontal plane (X-Y), as in the semiconductor bonding apparatus 10 according to Example 1, the magnetic field concentration effect and induction heating efficiency are more excellent.

In this way, the semiconductor bonding apparatus according to the comparative example has a limitation in that it may only inductively heat solder bumps 40 having a relatively large pitch p of 700 µm or more because the magnetic field is not effectively concentrated on the solder bump 40.

In contrast, the semiconductor bonding apparatus 10, 10A, 10B, 10C, 10D, 10E, 10F, or 10G according to an example implementation may heat solder bumps 40 having a pitch p of a much finer size (for example, 400 µm or less) than the comparative example to the melting point or higher when performing high-frequency induction heating using the same level of frequency. This is the result of the magnetic flux concentration on the solder bumps 40 by the shielding portion 120, 120C, 120D, 120F or 120G as described above, and the resulting improvement in high-frequency induction heating efficiency.

The semiconductor bonding apparatuses 10, 10A, 10B, 10C, 10D, 10E, 10F, and 10G according to the example implementations as described above may concentrate the magnetic field m generated by the magnetic induction coils 200, 200A and 200B to the solder bumps 40 by having magnetic cores 100, 100C, 100D, 100F and 100G and shielding portions 120, 120C, 120D, 120F and 120G on the tops of the core portions 110. By concentrating the magnetic field m in this manner, the efficiency of high-frequency induction heating may be improved, and solder bumps 40 interposed on the substrate 30 with a fine pitch p of 700 µm or less, which is otherwise difficult to solder by using an alternative semiconductor bonding apparatus, may be sufficiently heated to the melting point or higher. Accordingly, the soldering and packaging quality may be improved during semiconductor chip manufacturing.

As set forth above, a semiconductor bonding apparatus according to example implementations may concentrate a magnetic field generated by a magnetic induction coil onto a solder bump by having a magnetic core in which a shielding portion is provided on the top of the core portion. By concentrating the magnetic field in this way, the efficiency of high-frequency induction heating may be improved Furthermore, even when a solder bump is interposed on a substrate with a fine pitch of 700 µm or less, for which soldering would be difficult by using an alternative semiconductor bonding apparatus, may be sufficiently heated to a melting point or higher. Accordingly, the soldering and packaging quality may be further improved during semiconductor chip manufacturing.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While example implementations have been illustrated and described above, it will be apparent to those skilled in the art that modifications and variations could be made without departing from the scope of the present disclosure as defined by the appended claims.

What is claimed is:

1. A semiconductor bonding apparatus comprising:
a magnetic core including (i) a core portion extending in a direction and (ii) a shielding portion on a top of the core portion; and
a magnetic induction coil including a wire around the core portion of the magnetic core,
wherein the wire of the magnetic induction coil defines a hollow space that receives the core portion of the magnetic core,
wherein the wire of the magnetic induction coil is wound on a plane that crosses the direction, and
wherein the shielding portion of the magnetic core extends at least partially over an upper portion of the magnetic induction coil.

2. The semiconductor bonding apparatus of claim 1, wherein the core portion has a cylindrical shape having a first diameter, and
wherein the shielding portion has a disk shape having a second diameter greater than the first diameter.

3. The semiconductor bonding apparatus of claim 2, wherein the second diameter is smaller than a maximum outer diameter of the magnetic induction coil.

4. The semiconductor bonding apparatus of claim 2, wherein the second diameter is equal to or greater than a maximum outer diameter of the magnetic induction coil.

5. The semiconductor bonding apparatus of claim 1, wherein the wire of the magnetic induction coil is wound in a same direction to define a center, and
wherein the magnetic core is coaxially disposed to share the center with the magnetic induction coil.

6. The semiconductor bonding apparatus of claim 1, wherein a thickness of the shielding portion is smaller than a length of the core portion.

7. The semiconductor bonding apparatus of claim 1, wherein the core portion has a cylindrical shape with a first diameter, and
wherein the shielding portion includes a first shielding layer on the core portion and having a second diameter larger than the first diameter, and a second shielding layer on the first shielding layer and having a third diameter larger than the second diameter.

8. The semiconductor bonding apparatus of claim 1, wherein the magnetic core includes a shielding film protruding from an edge portion of the shielding portion and at least partially shielding an outer side of the magnetic induction coil.

9. The semiconductor bonding apparatus of claim 8, wherein the shielding film is in a form of a ring extending along a circumferential direction of the core portion.

10. The semiconductor bonding apparatus of claim 8, wherein a lower surface of the shielding film is on a same plane as a lower end of the magnetic induction coil.

11. The semiconductor bonding apparatus of claim 8, wherein the shielding film extends to a lower side of the magnetic induction coil.

12. The semiconductor bonding apparatus of claim 1, wherein the shielding portion includes a concave portion recessed from a lower surface of the shielding portion.

13. The semiconductor bonding apparatus of claim 1, comprising a cooler on a side of the magnetic core and configured to cool the core portion by blowing cooling gas toward the core portion and the magnetic induction coil.

14. The semiconductor bonding apparatus of claim 1, wherein the magnetic core includes a dust core.

15. A semiconductor bonding apparatus comprising:
a magnetic core including (i) a core portion extending in a first direction and (ii) a shielding portion on a top of the core portion; and
a magnetic induction coil including a wire around the core portion of the magnetic core,
wherein the wire of the magnetic induction coil defines a hollow space that receives the core portion of the magnetic core,
wherein the wire of the magnetic induction coil is wound in a spiral shape extending in a second direction crossing the first direction, and
wherein the shielding portion of the magnetic core extends at least partially over an upper portion of the magnetic induction coil.

16. The semiconductor bonding apparatus of claim 15, wherein the core portion has a cylindrical shape having a first diameter, and
wherein the shielding portion has a disk shape having a second diameter larger than the first diameter.

17. The semiconductor bonding apparatus of claim 16, wherein the second diameter of the shielding portion is equal to or greater than a maximum outer diameter of the magnetic induction coil, and
wherein a thickness of the shielding portion is thinner than a length of the core portion.

18. A semiconductor bonding apparatus comprising:
a magnetic core including (i) a core portion extending in a first direction and (ii) a shielding portion on a top of the core portion; and
a magnetic induction coil including a wire around the core portion of the magnetic core,
wherein the wire of the magnetic induction coil defines a hollow space that receives the core portion of the magnetic core,
wherein the wire of the magnetic induction coil is wound in a spiral shape that extends in a second direction crossing the first direction and that has a constant outer diameter; and
wherein the shielding portion of the magnetic core extends over an upper portion of the magnetic induction coil.

19. The semiconductor bonding apparatus of claim 18, wherein the core portion has a cylindrical shape having a first diameter, and
wherein the shielding portion has a disk shape having a second diameter greater than the first diameter.

20. The semiconductor bonding apparatus of claim 19, wherein the second diameter of the shielding portion is equal to or greater than a maximum outer diameter of the magnetic induction coil, and
wherein a thickness of the shielding portion is thinner than a length of the core portion.
